(19) United States
(12) Patent Application Publication
(10) Pub. No.: US 2026/0333704 A1
(43) Pub. Date: Oct. 22, 2026

(54) FERROELECTRIC TUNNEL JUNCTION WITH IMPROVED FERROELECTRIC RESPONSE AND FERROELECTRIC RANDOM ACCESS MEMORY EMPLOYING SAME

(71) Applicant: Taiwan Semiconductor Manufacturing Company, Ltd., Hsinchu (TW)

(72) Inventors: Wan-Chen Chen, Hsinchu (TW); Tzu-Yu Chen, Kaohsiung (TW); Chu-Jie Huang, Tainan (TW); Fu-Chen Chang, New Taipei (TW); Kuo-Chi Tu, Hsinchu (TW); Sheng-Hung Shih, Hsinchu (TW)

(21) Appl. No.: 19/710,587

(22) Filed: Jun. 17, 2026

Related U.S. Application Data
(63) Continuation of application No. 18/198,465, filed on May 17, 2023.

(51) Int. Cl. H10B 51/30; H10D 30/01; H10D 30/69; H10D 64/68

(52) U.S. Cl. CPC H10B 51/30; H10D 30/0415; H10D 30/701; H10D 64/689

(57) ABSTRACT

A ferroelectric tunnel junction is formed, comprising a plurality of layers including at least a bottom electrode layer, a top electrode layer, and at least one ferroelectric layer disposed between the bottom electrode layer and the top electrode layer. The at least one ferroelectric layer comprises a ferroelectric material. At least one layer of the plurality of layers is in contact with the ferroelectric layer and has a coefficient of thermal expansion that is at least 25% lower than a coefficient of thermal expansion of the ferroelectric layer; and inducing ferroelectric phase crystallization in the ferroelectric layer by annealing the plurality of layers.

This application is a continuation application of U.S. application Ser. No. 18/198,465 filed May 17, 2023, which is incorporated herein by reference in its entirety.

### BACKGROUND

The following relates to the integrated circuit (IC) arts, ferroelectric tunnel junction (FTJ) arts, ferroelectric random access memory (FeRAM) arts, and related arts.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 part (A) diagrammatically illustrates a ferroelectric tunnel junction (FTJ) structure along with a driving transistor that with the FTJ form a ferroelectric random access memory (FeRAM) cell. FIG. 1 part (B) diagrammatically illustrates cross-sectional views of the top electrode and ferroelectric material layers of a FTJ before, during, and after a thermal anneal diagrammatically depicted at the bottom portion.

FIG. 2, FIG. 3, and FIG. 4 diagrammatically illustrate additional FTJ structures suitable for use in a FeRAM.

FIG. 5 diagrammatically illustrates a cross-sectional view of an FTJ structure in which an interfacial layer is interposed between a ferroelectric material layer and a top electrode layer.

FIG. 6 diagrammatically illustrates a cross-sectional view of an FTJ structure in which an interfacial layer is interposed between the ferroelectric material layer and a bottom electrode layer.

FIG. 7 diagrammatically illustrates a cross-sectional view of an FTJ structure in which an interfacial layer is interposed between two ferroelectric material layers.

FIGS. 8-19 diagrammatically illustrate additional FTJ structures suitable for use in a FeRAM.

FIG. 20 diagrammatically illustrates a fabrication method for fabricating a FeRAM including an FTJ.

FIGS. 21-24 illustrate cross-sectional views of selected steps of one illustrative embodiment of the fabrication method of FIG. 20.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “about” can be used to include any numerical value that can vary without changing the basic function of that value. When used with a range, “about” also discloses the range defined by the absolute values of the one or two endpoints, e.g., “about 0.2 nanometers to about 5 nanometers” also discloses the range “0.2 nanometers to 5 nanometers”, and similarly the range “at least about 25% lower” also disclosed the range “at least 25% lower”. The term “about” may refer to plus or minus 10% of the indicated number.

A ferroelectric tunnel junction (FTJ) includes a thin ferroelectric layer made of a ferroelectric material, which is interposed between top and bottom electrodes. The remnant polarization of the ferroelectric layer can be switched between a positive remnant polarization often denoted as +Pr and a negative remnant polarization often denoted as −Pr. The electrical resistance of electrical current tunneling through the FTJ depends strongly on the polarization (+Pr or −Pr), so that measurement of current flow through the FTJ enables readout of the stored remnant polarization. The change in polarization between the +Pr state (which may, for example encode either a logical “1” or a logical “0”) and the −Pr state (which then encodes the other of logical “0” or logical “1”) is 2Pr. The plurality of layers making up the FTJ may include an additional interfacial layer that is interposed between the top and bottom electrodes and is in contact with the ferroelectric layer. The interfacial layer is chosen to engineer the characteristics of the tunnel barrier. A ferroelectric random access memory (FeRAM) includes a FTJ and a transistor, such as a field-effect transistor (FET), which is used to read and write bit values to the FeRAM which serves as nonvolatile storage for the FeRAM.

The fabrication process for fabricating an FTJ includes forming the plurality of layers (top and bottom electrodes with the ferroelectric layer and optional interfacial layer interposed therebetween) and annealing the plurality of layers at a temperature high enough to induce ferroelectric phase crystallization in the ferroelectric material of the ferroelectric layer. For a ferroelectric layer that has a thickness greater than about 5 nm, an anneal at a suitably high temperature for a suitably long time interval (e.g., about 550 °C for about 30 seconds in some examples) produces sufficient ferroelectric phase crystallization for the FTJ to operate with well-defined +Pr and −Pr values.

However, for a thinner ferroelectric layer, e.g. having a thickness of about 5 nm or less, it has been found to be more difficult to produce sufficient ferroelectric phase crystallization by annealing for the FTJ to operate with well-defined +Pr and −Pr values. Without being limited to any particular theory of operation, it is believed that for an FTJ structure with a thin ferroelectric layer (e.g., about 5 nm or thinner) the anneal produces ferroelectric phase crystallization that is incomplete and/or spatially varying across the area of the ferroelectric layer, leading to local variation of the 2Pr value across the area of the ferroelectric layer and consequent problems such as electrical current leakage, variable capacitance, and so forth.

In embodiments disclosed herein, this problem is overcome by introducing a stress-versus-time profile to the ferroelectric layer during the annealing process. Compressive biaxial stress is applied to the ferroelectric layer during the high temperature time period of the anneal using at least one layer of the plurality of layers that has the coefficient of thermal expansion (CTE) that is at least about 25% lower than (and in some embodiments about one-half or less than) the CTE of the ferroelectric layer. During the subsequent cooldown time period, tensile biaxial stress is applied to the ferroelectric layer using the at least one layer of the plurality of layers that has the CTE that is at least about 25% lower than (and in some embodiments about one-half or less than) the CTE of the ferroelectric layer. Without being limited to any particular theory of operation, it is believed that this stress-versus-time profile operates to promote the ferroelectric phase crystallization process, leading to greater 2Pr uniformity over the area of the ferroelectric layer and consequently reduced electrical current leakage, more uniform capacitance, and so forth.

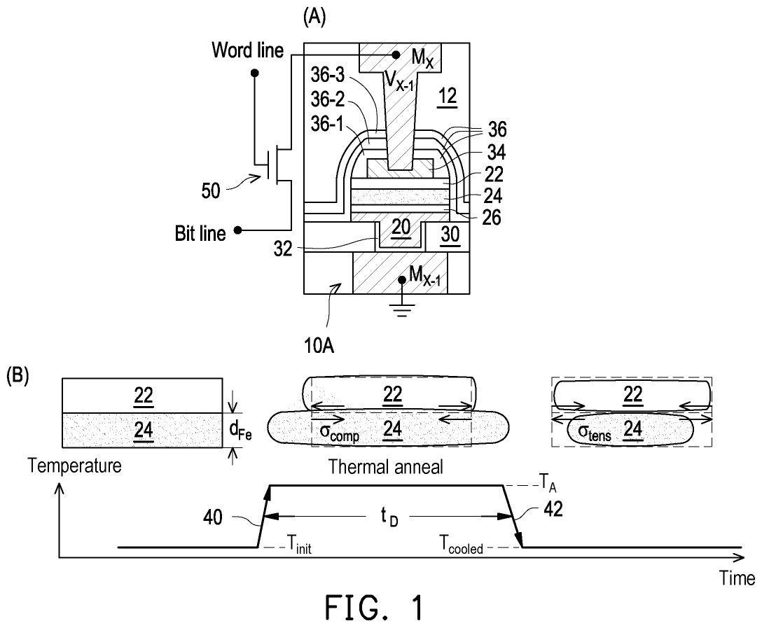

With reference to FIG. 1 part (A), an illustrative ferroelectric tunnel junction (FTJ) 10A is shown. The FTJ 10A is formed between a lower metallization layer denoted as Mₓ₋₁ and an upper metallization layer denoted as Mₓ. The metallization layer Mₓ₋₁ is “lower” than the metallization layer Mₓ in that the metallization layer Mₓ₋₁ is closer to the semiconductor substate (e.g., a silicon wafer in some nonlimiting illustrative examples) than is the metallization layer Mₓ. In some nonlimiting illustrative embodiments, the metallization layers Mₓ₋₁ and Mₓ are patterned layers of copper or copper alloy layers forming electrical traces of an integrated circuit (IC) formed on and/or in the semiconductor substrate. In some nonlimiting illustrative examples, the metallization layers Mₓ₋₁ and Mₓ may be metallization layers of middle end-of-line (MEOL) processing or back end-of-line (BEOL) processing of the overall IC manufacturing process. The metallization layers are formed in or surrounded or encapsulated by an intermetal dielectric (IMD) material 12. The IMD material 12 may, by way of some nonlimiting illustrative examples, comprise polysilicon, silicon oxide, silicon nitride, silicon oxynitride, phosphosilicate glass (PSG), borophosphosilicate glass (BPSG), spin-on glass (SOG), fluoride-doped silicate glass (FSG), carbon doped silicon oxide (SiCOH), polyimide, amorphous fluorinated carbon, bis-benzocyclobutenes (BCB), hydrogen silsesquioxane, fluorinated silicon oxide (SiOF), and/or combinations thereof.

The FTJ 10A comprises a plurality of layers including at least a bottom electrode layer 20, a top electrode layer 22, and a ferroelectric layer 24 disposed between the bottom electrode layer 20 and the top electrode layer 22. In some embodiments, the ferroelectric layer 24 is a thin layer, for example having a thickness of about 5 nm or less (that is, five nanometers or less). In the illustrative FTJ 10A, the plurality of layers further includes an interfacial layer 26 that is disposed between the bottom electrode layer 20 and the top electrode layer 22. The interfacial layer 26 is in contact with the ferroelectric layer 24. In some nonlimiting illustrative embodiments, the interfacial layer 26 has a thickness of between about 0.2 nanometers and about 5 nanometers. The thickness and composition of the optional interfacial layer 26 is suitably designed to tailor properties of operation of the ferroelectric tunneling junction. However, as disclosed herein, in some embodiments the interfacial layer 26 may additionally beneficially provide confinement of thermal expansion and contraction of the ferroelectric layer 24 to promote ferroelectric phase crystallization in the ferroelectric layer 24 during annealing.

In the illustrative example of FIG. 1 part (A), the bottom electrode layer 20 of the FTJ 10A is formed by depositing a dielectric layer 30 (such as, by nonlimiting illustrative example, a silicon carbide (SiC) layer 30), photolithographically defining a hard mask region 32, depositing the bottom electrode layer 20 followed by the interfacial layer 26, the ferroelectric layer 24, and the top electrode layer 22. The bottom electrode layer 20 is electrically connected with the metallization layer Mₓ₋₁. After formation of the plurality of layers 20, 22, 24, 26, a second hard mask 34 is formed on the top electrode layer 22 which serves to delineate contact of the top electrode layer 22 with a via Vₓ₋₁that in turn connects with the metallization layer Mₓ so that the top electrode layer 22 is electrically connected with the metallization layer Mₓ. The FTJ 10A may include other optional elements such as dielectric spacers, insulating layers or coatings, stress release features, or the like 36 to encapsulate, electrically isolate, relieve stress, or otherwise protect or delineate the FTJ 10A. The nonlimiting illustrative example includes a spacer layer 36-1 that is disposed over the top electrode 22 and the second hard mask 34. A top etch stop layer 36-2 is disposed over the spacer layer 36-1 and over the ferroelectric layer 24 and interface layer 26 and a portion of the bottom electrode 20 The etch stop layer 36-2 suitably comprises a dielectric material such as SiCN, SiCO, SiO₂, SIN, SiC, A1ON or the like. A protective liner layer 36-3 is disposed on the etch stop layer 36-2, and can for example comprise a low-dielectric material such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

The FTJ 10A shown in FIG. 1 part (A) is vertically oriented with the via Vₓ₋₁ positioned centrally over the top electrode layer 22, and in the FTJ 10A the ferroelectric layer 24 is a planar layer.

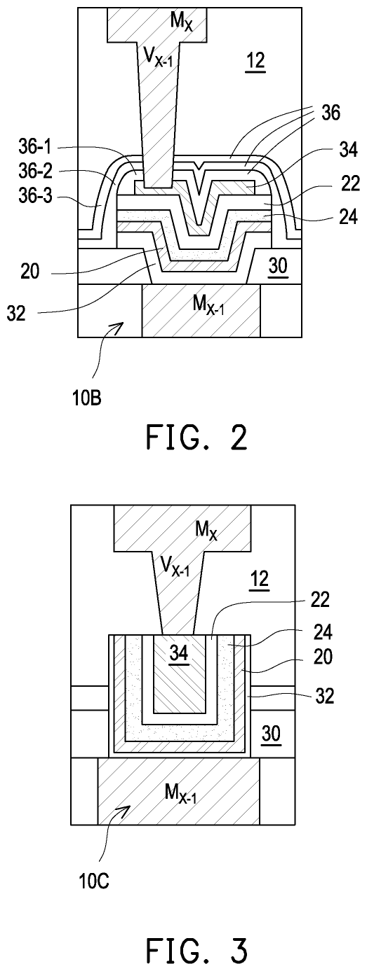

However, with reference to FIGS. 2, 3, and 4, numerous variant FJT designs are contemplated, some nonlimiting examples of which are presented in the cross-sectional views of FIGS. 2, 3, and 4. FIG. 2 illustrates an FTJ 10B in which the bottom electrode layer 20, the ferroelectric layer 24, and the top electrode layer 22 each have a flat bottom portion, slanted sidewalls, and a flat edge portion. In the FTJ 10B, the via Vₓ₋₁ is positioned off-center respective to the top electrode layer 22, contacting at the top flat edge portion of the top electrode layer 22. The FTJ 10B also includes the second hard mask 34 and additional layers 36 including the spacer layer 36-1 disposed over the hard mask 34, the top etch stop layer 36-2 disposed over the spacer 36-1, top electrode 22, the ferroelectric layer 24, and a portion of the bottom electrode 20, and the protective liner 36-3. The etch stop layer 36-2 suitably comprises a dielectric material such as SiCN, SiCO, SiO₂, SIN, SiC, AlON or the like. The protective liner layer 36-3 suitably comprises a low-dielectric material such as TEOS, un-doped silicate glass, or doped silicon oxide such as BPSG, FSG, PSG, BSG, and/or other suitable dielectric materials.

FIG. 3 shows another example FTJ 10C in which the bottom electrode layer 20, the ferroelectric layer 24, and the top electrode layer 22 each have a “U”-shape with a flat bottom and transverse vertical sidewall. In the FTJ 10C, the via Vₓ₋₁ is positioned on-center respective to the top electrode layer 22, contacting at the top flat edge portion of the top electrode layer 22. The FTJ 10C of FIG. 3 does not include the additional layers 36 of the FTJ 10A and FTJ 10B of respective FIGS. 1A and 2.

FIG. 4 shows another example FTJ 10D which is similar to the FTJ 10A shown in FIG. 1 part (A), and includes the second hard mask 34 and the additional layers 36 of the FTJ 10A. In the FTJ 10D of FIG. 4, the spacer layer 36-1 is disposed over the hard mask 34, the top electrode 22, the ferroelectric layer 24, and a portion of the bottom electrode 20. The top etch stop layer 36-2 is disposed over the spacer 36-1, and the protective liner is disposed over the etch stop layer 36-2. The etch stop layer suitably comprising a dielectric material such as SiCN, SiCO, SiO₂, SIN, SiC, A1ON or the like. The protective liner layer 36-3 suitably comprises a low-dielectric material such as TEOS, un-doped silicate glass, or doped silicon oxide such as BPSG, FSG, PSG, BSG, and/or other suitable dielectric materials.

In each of the foregoing examples, i.e. FTJ 10A, FTJ 10B, FTJ 10C, and FTJ 10D, the plurality of layers making up the FTJ include at least the bottom electrode layer 20, the top electrode layer 22, and at least one ferroelectric layer 24 disposed between the bottom electrode layer 20 and the top electrode layer 22. The example FTJ 10A further includes the interfacial layer 26, while FTJ 10B, FTJ 10C, and FTJ 10D do not include this layer.

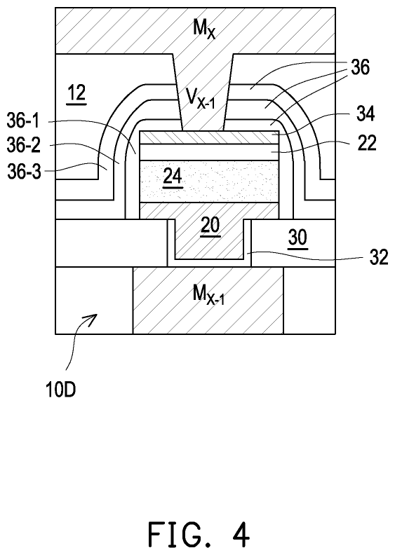

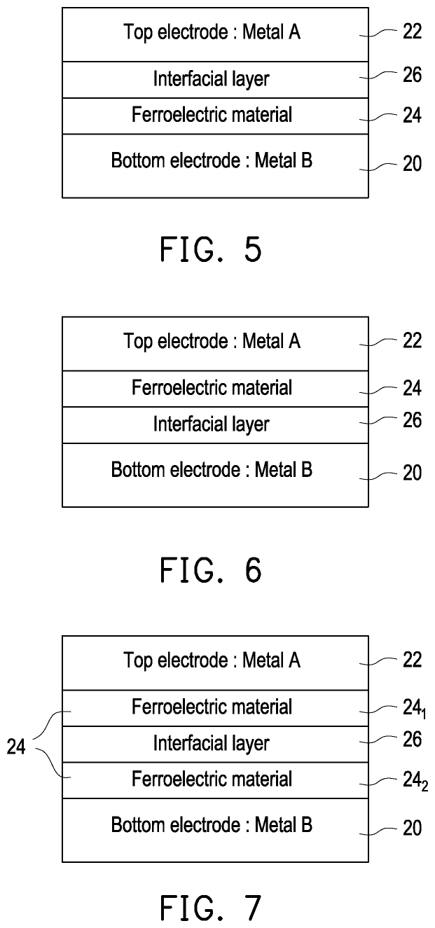

With brief reference to FIGS. 5, 6, and 7, some further example FTJ structures are shown, which also include the interfacial layer 26. The example of FIG. 5 has an arrangement similar to that of FTJ 10A of FIG. 1 part (A), in which the interfacial layer 26 is disposed between the ferroelectric layer 24 and the top electrode layer 22. The example of FIG. 6 has an arrangement in which the interfacial layer 26 is disposed between the ferroelectric layer 24 and the bottom electrode layer 20. The example of FIG. 7 has an arrangement in which the interfacial layer 26 is disposed inside the ferroelectric layer 24, so that the interfacial layer 26 divides the ferroelectric layer 24 into a first (e.g. upper) ferroelectric layer 241 and a second (e.g. lower) ferroelectric layer 242. These are merely illustrative configuration. In each case, the ferroelectric layer 24 is disposed between the bottom electrode layer 20 and the top electrode layer 22, and the interfacial layer 26 is also disposed between the bottom electrode layer 20 and the top electrode layer 22.

The FTJ structures of FIGS. 5, 6, and 7 can be variously employed in any of FTJ 10A, FTJ 10B, FTJ 10C, or FTJ 10D, or in other FTJ structures. FIG. 1 illustrates the FTJ 10A employing the FTJ structure of FIG. 5, while FIGS. 2, 3, and 4 illustrate FTJ 10B, FTJ 10C, and FTJ 10D each using the ferroelectric layer 24 in contact with the bottom electrode 20 and the top electrode 22. Some further examples follow.

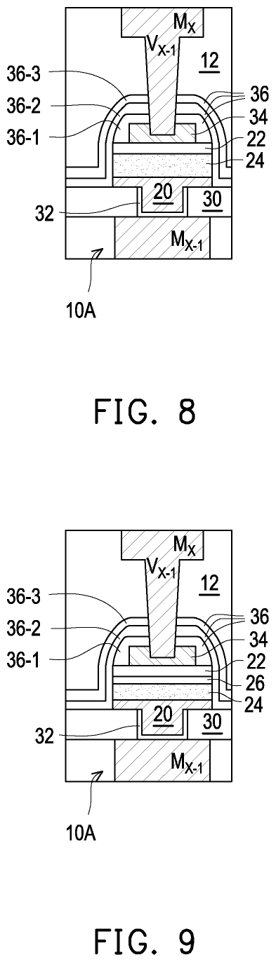

FIG. 8 illustrates an embodiment of the FTJ 10A of FIG. 1 part (A), with the interfacial layer 26 omitted. Thus, in the structure of FIG. 8, the ferroelectric layer 24 is disposed on the bottom electrode 20, and the top electrode 22 is disposed on the ferroelectric layer 24. In this embodiment, the ferroelectric layer is in direct contact with the bottom electrode 20 and is in direct contact with the top electrode 22.

FIG. 9 illustrates an embodiment of the FTJ 10A of FIG. 1 part (A), employing the FTJ structure of FIG. 6. Thus, in the structure of FIG. 9, the ferroelectric layer 24 is disposed on the bottom electrode 20, the interfacial layer 26 is disposed on the ferroelectric layer 24, and the top electrode 22 is disposed on the interfacial layer 26. In this embodiment, the ferroelectric layer is disposed between and in direct contact with the bottom electrode 20 and the interfacial layer 26.

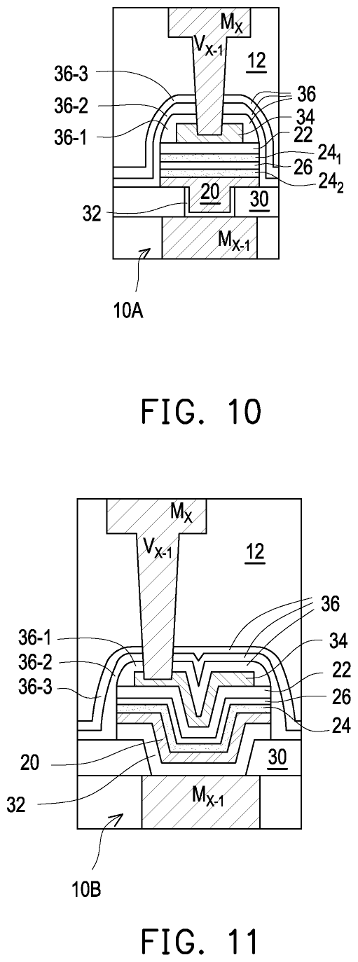

FIG. 10 illustrates an embodiment of the FTJ 10A of FIG. 1 part (A), employing the FTJ structure of FIG. 7. Thus, in the structure of FIG. 10, a second (e.g. lower) ferroelectric layer 242 is disposed on the bottom electrode 20, the interfacial layer 26 is disposed on the second ferroelectric layer 24₂, a first (e.g. upper) ferroelectric layer 24₁ is disposed on the interfacial layer 26, and the top electrode 22 is disposed on the first ferroelectric layer 241. In this embodiment, the lower ferroelectric layer 24₂ is disposed between and in direct contact with the bottom electrode 20 and the interfacial layer 26; and the upper ferroelectric layer 24₁ is disposed between and in direct contact with the interfacial layer 26 and the top electrode 22.

FIG. 11 illustrates an embodiment of the FTJ 10B of FIG. 2, employing the FTJ structure of FIG. 5. Thus, in the structure of FIG. 11, the ferroelectric layer 24 is disposed on the bottom electrode 20, the interfacial layer 26 is disposed on the ferroelectric layer 24, and the top electrode 22 is disposed on the interfacial layer 26. In this embodiment, the ferroelectric layer is disposed between and in direct contact with the bottom electrode 20 and the interfacial layer 26.

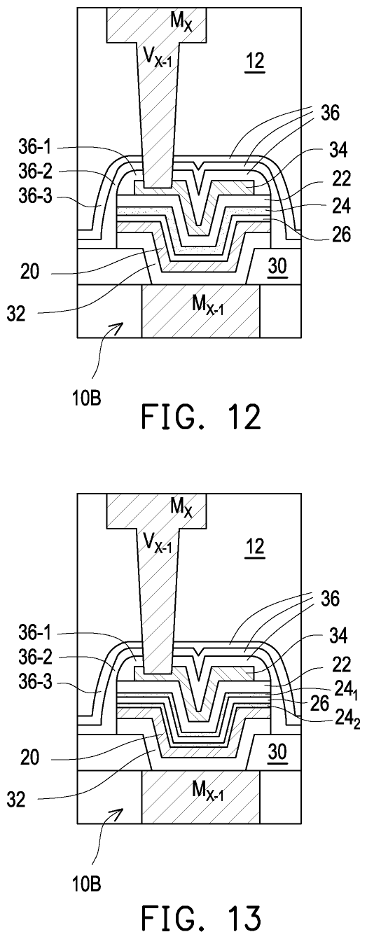

FIG. 12 illustrates an embodiment of the FTJ 10B of FIG. 2, employing the FTJ structure of FIG. 6. Thus, in the structure of FIG. 12, the interfacial layer 26 is disposed on the bottom electrode 20, the ferroelectric layer 24 is disposed on the interfacial layer 26, and the top electrode 22 is disposed on the ferroelectric layer 24. In this embodiment, the ferroelectric layer is disposed between and in direct contact with the interfacial layer 26 and the top electrode 22.

FIG. 13 illustrates an embodiment of the FTJ 10B of FIG. 2, employing the FTJ structure of FIG. 7. Thus, in the structure of FIG. 13, a second (e.g. lower) ferroelectric layer 24₂ is disposed on the bottom electrode 20, the interfacial layer 26 is disposed on the second ferroelectric layer 24₂, a first (e.g. upper) ferroelectric layer 24₁ is disposed on the interfacial layer 26, and the top electrode 22 is disposed on the first ferroelectric layer 24₁. In this embodiment, the lower ferroelectric layer 242 is disposed between and in direct contact with the bottom electrode 20 and the interfacial layer 26; and the upper ferroelectric layer 24₁ is disposed between and in direct contact with the interfacial layer 26 and the top electrode 22.

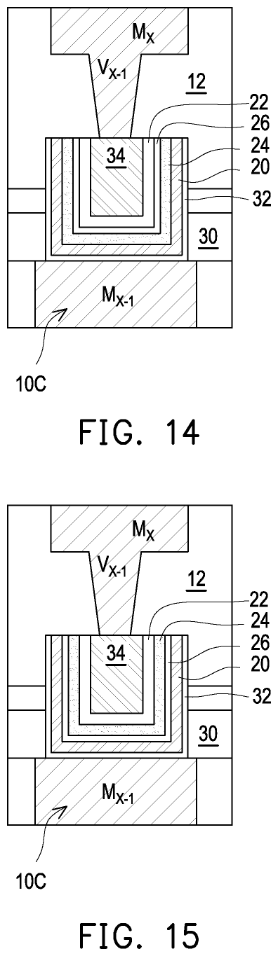

FIG. 14 illustrates an embodiment of the FTJ 10C of FIG. 3, employing the FTJ structure of FIG. 5. Thus, in the structure of FIG. 14, the ferroelectric layer 24 is disposed on the bottom electrode 20, the interfacial layer 26 is disposed on the ferroelectric layer 24, and the top electrode 22 is disposed on the interfacial layer 26.

In this embodiment, the ferroelectric layer is disposed between and in direct contact with the bottom electrode 20 and the interfacial layer 26.

FIG. 15 illustrates an embodiment of the FTJ 10C of FIG. 3, employing the FTJ structure of FIG. 6. Thus, in the structure of FIG. 15, the interfacial layer 26 is disposed on the bottom electrode 20, the ferroelectric layer 24 is disposed on the interfacial layer 26, and the top electrode 22 is disposed on the ferroelectric layer 24. In this embodiment, the ferroelectric layer is disposed between and in direct contact with the interfacial layer 26 and the top electrode 22.

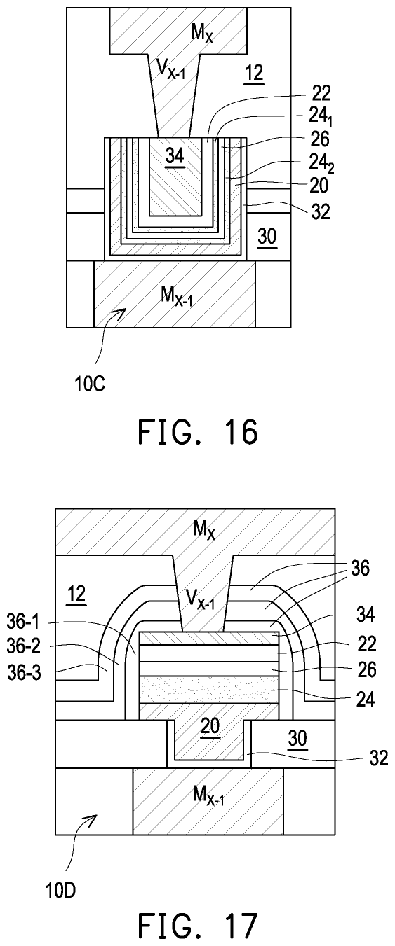

FIG. 16 illustrates an embodiment of the FTJ 10C of FIG. 3, employing the FTJ structure of FIG. 7. Thus, in the structure of FIG. 16, a second (e.g. lower) ferroelectric layer 24₂ is disposed on the bottom electrode 20, the interfacial layer 26 is disposed on the second ferroelectric layer 24₂, a first (e.g. upper) ferroelectric layer 24₁ is disposed on the interfacial layer 26, and the top electrode 22 is disposed on the first ferroelectric layer 24₁. In this embodiment, the lower ferroelectric layer 24₂ is disposed between and in direct contact with the bottom electrode 20 and the interfacial layer 26; and the upper ferroelectric layer 24₁ is disposed between and in direct contact with the interfacial layer 26 and the top electrode 22.

FIG. 17 illustrates an embodiment of the FTJ 10D of FIG. 4, employing the FTJ structure of FIG. 5. Thus, in the structure of FIG. 17, the ferroelectric layer 24 is disposed on the bottom electrode 20, the interfacial layer 26 is disposed on the ferroelectric layer 24, and the top electrode 22 is disposed on the interfacial layer 26. In this embodiment, the ferroelectric layer is disposed between and in direct contact with the bottom electrode 20 and the interfacial layer 26.

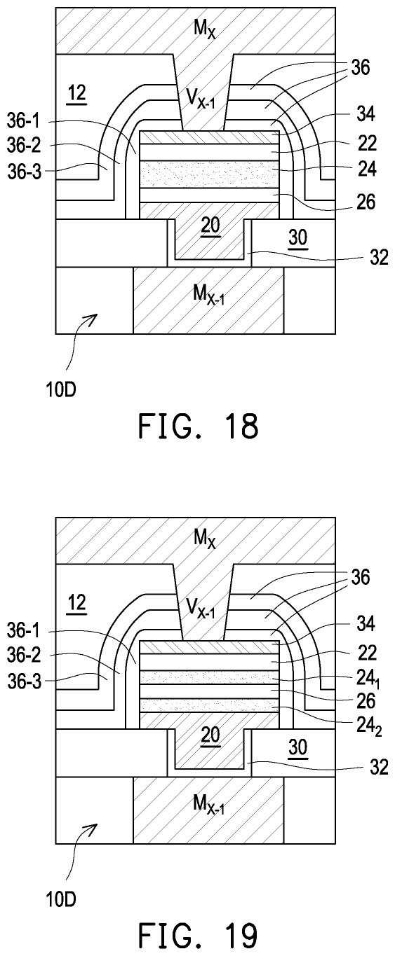

FIG. 18 illustrates an embodiment of the FTJ 10D of FIG. 4, employing the FTJ structure of FIG. 6. Thus, in the structure of FIG. 18, the interfacial layer 26 is disposed on the bottom electrode 20, the ferroelectric layer 24 is disposed on the interfacial layer 26, and the top electrode 22 is disposed on the ferroelectric layer 24. In this embodiment, the ferroelectric layer is disposed between and in direct contact with the interfacial layer 26 and the top electrode 22.

FIG. 19 illustrates an embodiment of the FTJ 10D of FIG. 4, employing the FTJ structure of FIG. 7. Thus, in the structure of FIG. 19, a second (e.g. lower) ferroelectric layer 24₂ is disposed on the bottom electrode 20, the interfacial layer 26 is disposed on the second ferroelectric layer 24₂, a first (e.g. upper) ferroelectric layer 24₁ is disposed on the interfacial layer 26, and the top electrode 22 is disposed on the first ferroelectric layer 24₁. In this embodiment, the lower ferroelectric layer 24₂ is disposed between and in direct contact with the bottom electrode 20 and the interfacial layer 26; and the upper ferroelectric layer 24₁ is disposed between and in direct contact with the interfacial layer 26 and the top electrode 22.

The examples of FIGS. 1 part (A), 2-4, and 8-19 are to be understood as nonlimiting illustrative examples, and more generally the disclosed approaches for facilitating formation of ferroelectric phase crystallization in the ferroelectric layer by annealing the plurality of layers can be employed with other FTJ configurations, as described in further detail below.

The ferroelectric layer 24 is made of a ferroelectric material such as hafnium oxide doped with zinc, silicon, yttrium, aluminum, gadolinium, lanthanum, or strontium. As a specific example, when zinc is the dopant the material is sometimes referred to as hafnium zinc oxide (HZO), corresponding to a composition Hf₁₋ₓZrₓ0₂ with x in a range of about 0.4≤x<0.7. More generally, the composition could be Hf₁₋ₓDₓ0₂ where the dopant D can be zinc, silicon, yttrium, aluminum, gadolinium, lanthanum, or strontium, for example, and the composition fraction x is chosen to provide a desired ferroelectric property. In other embodiments, the ferroelectric layer 24 may comprise another type of ferroelectric material such as SrBi₂Ta₂O₉, PbZrₓTi₁₋ₓO₃, or BaTiO₃. These are merely some nonlimiting illustrative examples.

In one fabrication process, the ferroelectric layer 24 in its as-deposited state is an amorphous material, or a polycrystalline or single crystal material with various crystal phases. For proper operation of the ferroelectric tunnel junction, a sufficient portion of the ferroelectric layer 24 should be in a ferroelectric crystal phase. For the example of HZO, a suitable ferroelectric crystal phase is an orthorhombic phase, which is non-centrosymmetric with oxygen atoms are arranged to be able to respond to form intrinsic polarizations in response to external electric fields, thereby being capable of being switched by application of electric field between positive remnant polarization (+Pr) and negative remnant polarization (−Pr) states. The ferroelectric behavior of the orthorhombic crystal phase of HZO is a consequence of its non-centrosymmetric crystal structure. However, the as-deposited ferroelectric layer 24 may be amorphous, or may have a mixture of phases, e.g. a mixture of tetragonal and/or monoclinic and/or orthorhombic crystal phases. Characterization techniques such as X-ray diffraction (XRD) and/or electron backscatter diffraction (EBSD) can be used to assess the fractional phases of the layer 24.

To perform as a ferroelectric tunnel junction, the ferroelectric layer 24 should have a sufficiently high fraction of its material in a ferroelectric crystal phase (e.g., in the orthorhombic phase in the case of HZO or some other hafnium oxide-based ferroelectric materials). One way to induce the material of the layer 24 into the ferroelectric crystal phase is ferroelectric phase crystallization by annealing. This can occur spontaneously in response to annealing at a suitably high temperature for a sufficient time interval (e.g., ~550 °C for about 5 minutes may be sufficient in some cases). However, for a thin ferroelectric layer, e.g. having a thickness of about 5 nm or less, it has been found to be difficult to produce sufficient ferroelectric phase crystallization by annealing to achieve satisfactory ferroelectric tunnel junction operation. This difficulty is believed to be due to the anneal producing ferroelectric phase crystallization that is incomplete and/or spatially varying across the area of the ferroelectric layer.

One way to enhance the ferroelectric phase crystallization may be to employ a higher annealing temperature. However, the ferroelectric tunnel junction is sometimes formed during MEOL or BEOL processing, which is after the front end-of-line (FEOL) processing is complete. Consequently, there can be limits on the annealing temperature, e.g. excessively high annealing temperature can damage the metallization layers Mₓ₋₁ and Mₓ and/or the metal vias Vₓ₋₁ (see FIG. 1 part (A) and FIGS. 2-4). Another approach might be to add an additional “seed” layer to the FTJ stack. Such a seed layer can be chosen to undergo phase crystallization during annealing to crystallize into a crystal phase that serves as a template for ferroelectric phase crystallization of the ferroelectric layer. However, this approach entails adding an additional layer to the FTJ stack (that is, in addition to the bottom and top electrode layers 20 and 22, the ferroelectric layer 24, and the optional interfacial layer 26), which increases the fabrication process complexity.

In embodiments disclosed herein, ferroelectric phase crystallization is obtained for the ferroelectric layer 24 with a thickness of about 5 nm or less by introducing a stress-versus-time profile to the ferroelectric layer 24 during the annealing process. Compressive biaxial stress is applied to the ferroelectric layer during the high temperature time period of the anneal using at least one layer of the plurality of layers that has the coefficient of thermal expansion (CTE) that is at least about 25% lower than (and in some embodiments about one-half or less than) the CTE of the ferroelectric layer 24. During the subsequent cooldown time period, tensile biaxial stress is applied to the ferroelectric layer 24 using the at least one layer of the plurality of layers that has the CTE that is at least about 25% lower than (and in some embodiments about one-half or less than) the CTE of the ferroelectric layer. The stress-versus-time profile is believed to operate to promote the ferroelectric phase crystallization process without the addition of a seed layer, leading to greater 2Pr uniformity over the area of the ferroelectric layer and consequently improved FTJ performance as indicated by metrics such as reduced electrical current leakage, more uniform capacitance, and so forth.

With returning reference now to FIG. 1 part (B), a suitable thermal anneal of an FTJ to induce ferroelectric phase crystallization in the ferroelectric layer 24 is depicted in the lower portion of part (B) as a temperature versus time plot. The FTJ undergoing the ferroelectric phase crystallization has the structure depicted in FIG. 1 part (A). (Alternatively, it could have one of the structure depicted in FIGS. 2-19, as further nonlimiting examples). The ferroelectric layer 24 has a thickness of about 5 nm or less, which as noted previously makes the ferroelectric phase crystallization challenging. In this regard, for the example FTJ structure of FIG. 7 in which the ferroelectric layer 24 is divided into two sub-layers 241 and 242 by the interposed interfacial layer 26, the thickness of the ferroelectric layer 24 is the combined thicknesses of the ferroelectric layer 24₁ and ferroelectric layer 24₂. That is, designating the thickness of the ferroelectric layer 24₁ as di and the thickness of the ferroelectric layer 24₂ as d₂, the thickness of the at least one ferroelectric layer 24₁, 24₂ is d1+d2. As shown in the temperature-versus-time anneal schedule diagrammatically depicted in FIG. 1 part (B), the FTJ is at an initial temperature Tᵢₙᵢₜ, and to initiate the anneal the temperature is ramped up over a temperature ramp-up 40 to an anneal temperature T_{A}, which is maintained over a (dwell) time interval tp which is followed by a temperature ramp-down 42 over which the temperature is cooled down to a cooled temperature T_{cooled}. In a typical embodiment, the temperatures Tᵢₙᵢₜ and T_{cooled} are about the same, for example both Tᵢₙᵢₜand T_{cooled} may be in a room temperature range of about 20 °C to about 25 °C. However, in some embodiments one or both of the temperatures Tᵢₙᵢₜ and/or T_{cooled} may be different from room temperature, for example, the final temperature T_{cooled} may be some temperature at which the semiconductor wafer supporting the FTJ is transferred to another tool for further processing. Hence, in some more general embodiments Tc_{ooled} is 100 °C or lower. The anneal temperature Tₐₙₙₑₐₗ is chosen (along with the dwell time tp) to provide the desired ferroelectric phase crystallization of the ferroelectric layer 24. In some nonlimiting illustrative embodiments T_{A} may be in a range of 400 °C to 1000 °C, for example. In some embodiments, T_{A} may be a temperature of at least 350 °C. In some embodiments where the FTJ is part of MEOL or BEOL processing, there may be an upper limit imposed on T_{A} to avoid damaging the metallization layers Mₓ₋₁, Mₓ and/or vias Vₓ₋₁. For example, this upper limit may be 600 °C or lower in some nonlimiting illustrative embodiments.

With continuing reference to FIG. 1 part (B), above the temperature versus time plot are shown diagrammatic representations of a portion of the ferroelectric layer 24 and a portion of the top electrode layer 22. In this example, the top electrode layer 22 is in contact with the ferroelectric layer 24, and additionally the top electrode layer 22 has a coefficient of thermal expansion (CTE) that is at least about 25% lower than a CTE of the ferroelectric layer 24. In some embodiments, the top electrode layer 22 has a CTE that is less than or equal to about one-half of the CTE of the ferroelectric layer 24. As seen in the diagrammatic representation of the layer portions 22 and 24 in FIG. 1 part (B) for the time interval before the temperature ramp-up 40, prior to the anneal the top electrode layer 22 and the ferroelectric layer 24 are not under biaxial stress due to the difference in CTE of the two layers 22 and 24. During the ramp-up 40, however, the ferroelectric layer 24 expands more rapidly than the top electrode layer 22 due to the higher CTE of the ferroelectric layer 24 compared with the lower CTE of the top electrode layer 22. This difference in the rate of thermal expansion imposes a compressive biaxial stress δ_{comp} in the ferroelectric layer 24, as indicated by arrows in the diagrammatic depiction above the dwell time tp of the anneal schedule. During the subsequent ramp-down 42, the ferroelectric layer 24 contracts more rapidly than the top electrode layer 22, again due to the higher CTE of the ferroelectric layer 24 compared with the lower CTE of the top electrode layer 22. This imposes a tensile biaxial stress σₜₑₙₛ in the ferroelectric layer 24, as indicated by arrows in the diagrammatic depiction above the time interval after the ramp-down 42.

As recognized herein, this biaxial stressing of the ferroelectric layer 24 during the anneal promotes the inducing of ferroelectric phase crystallization in the ferroelectric layer 24. For examples in which the ferroelectric layer 24 comprises HZO (or another suitably doped hafnium oxide composition), the biaxial stressing of the HZO layer 24 during the anneal promotes the inducing of ferroelectric orthorhombic phase crystallization in the ferroelectric HZO layer 24. For an illustrative example in which the ferroelectric layer 24 is HZO (or another suitably doped hafnium oxide composition), the ferroelectric phase crystallization produced by the anneal may be at least 35% orthorhombic crystal phase, or at least 50% orthorhombic crystal phase, or at least 70% orthorhombic crystal phase, in some nonlimiting illustrative examples. The remainder of the HZO may, for example, be in a tetragonal phase and/or a monoclinic phase or so forth.

In the example of FIG. 1 part (B), the layer that provides the biaxial stressing δ_{comp} and δ_{comp} is the top electrode layer 22 which is in contact with the ferroelectric layer 24 and has a CTE that is at least about 25% lower than the CTE of the ferroelectric layer 24. However, more generally it is sufficient for at least one layer of the plurality of layers to be in contact with the ferroelectric layer 24 and to have a CTE that is at least about 25% lower than (and in some embodiments about one-half or less than) the CTE of the ferroelectric layer 24.

For example, in the FTJs 10B, 10C, and 10D of respective FIGS. 2, 3, and 4, the ferroelectric layer 24 is in contact with the top electrode layer 22 and is in contact with the bottom electrode layer 20. Hence, either the top electrode layer 22 or the bottom electrode layer 20, or both, could suitably have a CTE that is at least about 25% lower than (and in some embodiments about one-half or less than) the CTE of the ferroelectric layer 24, so as to induce the biaxial stressing δ_{comp} and δₜₑₙₛ in the ferroelectric layer 24 during the anneal.

In the FTJ 10A of FIG. 1 part (A) and in each of the FTJ structures shown in FIGS. 6, 12, 15, and 18, the ferroelectric layer 24 is in contact with the top electrode layer 22 and is in contact with the interfacial layer 26. Hence, either the top electrode layer 22 or the interfacial layer 26, or both, could suitably have a CTE that is at least about 25% lower than (and in some embodiments about one-half or less than) the CTE of the ferroelectric layer 24, so as to induce the biaxial stressing δ_{comp} and δₜₑₙₛ in the ferroelectric layer 24 during the anneal.

In each of the FTJ structures of FIGS. 5, 9, 11, 14, and 17, the ferroelectric layer 24 is in contact with the bottom electrode layer 20 and is in contact with the interfacial layer 26. Hence, either the bottom electrode layer 20 or the interfacial layer 26, or both, could suitably have a CTE that is at least about 25% lower than (and in some embodiments about one-half or less than) the CTE of the ferroelectric layer 24, so as to induce the biaxial stressing δ_{comp} and δₜₑₙₛ in the ferroelectric layer 24 during the anneal.

In each of the FTJ structures of FIGS. 7, 10, 13, 16, and 19, the ferroelectric layer 24 (collectively indicating the layers 24₁ and 24₂) is in contact with the bottom electrode layer 20 and is in contact with the interfacial layer 26 and is in contact with the top electrode layer 22. Hence, any combination of one or more of the bottom electrode layer 20, the interfacial layer 26, and/or the top electrode layer 22 could suitably have a CTE that is at least about 25% lower than (and in some embodiments about one-half or less than) the CTE of the ferroelectric layer 24, so as to induce the biaxial stressing σ_{comp} and Otens in the ferroelectric layer 24 during the anneal. In particular, if the interfacial layer 26 sandwiched between the ferroelectric layers 24₁ and 24₂ has a CTE that is at least about 25% lower than (and in some embodiments about one-half or less than) the CTE of the ferroelectric layers 24₁ and 24₂, then the interfacial layer 26 can provide the desired biaxial stressing σ_{comp} and σₜₑₙₛ in both ferroelectric layers 24₁ and 24₂ during the anneal. In such embodiments, the interfacial layer 26 disposed between and directly contacting both ferroelectric layers 24₁ and 24₂ beneficially provides for both tailoring properties of operation of the ferroelectric tunneling junction and also beneficially providing confinement of thermal expansion and contraction of the ferroelectric layer 24 to promote ferroelectric phase crystallization in the ferroelectric layer 24 during annealing.

In the following, some more specific examples are given.

The percent difference in the CTE between the ferroelectric layer 24 and the layer providing the biaxial stressing σ_{comp} and σₜₑₙₛ thereto is denoted herein as ΔCTE. This is suitably computed according to:

$$Δ CTE = \frac{\vert {CTE}_{Fe} - {CTE}_{material} \vert}{{CTE}_{F e}} \times 100 \% \qquad ( 1 )$$

where CTE_{Fe} is the coefficient of thermal expansion of the ferroelectric material 24, and CTEₘₐₜₑᵣᵢₐₗ is the coefficient of thermal expansion of the layer providing the biaxial stressing σ_{comp} and σₜₑₙₛ thereto. Table 1 lists some illustrative materials along with the coefficient of thermal expansion (CTE) of the material in units of

$$\frac{μ m}{m \cdot K}$$

(that is, μm·(m·K)⁻¹) and the percent difference in CTE (i.e., ΔCTE) with respect to hafnium zirconium oxide (HZO) having a composition Hf₁₋ₓZrₓO₂ with x in a range of about 0.4≤x≤0.7. As further listed at the end of Table 1, HZO has a CTE of about 30.

TABLE 1

| Material | $CTE ( \frac{μ m}{m \cdot K} )$ | ΔCTE |
|---|---|---|
| Silicon nitride (SiN) | 3.27 | 89% |
| Tantalum oxide (TaO) | 3.6 | 88% |
| Tantalum nitride (TaN) | 4.2-4.5 | 85%-86% |
| Tungsten (W) | 4.3 | 86% |
| Molybdenum (Mo) | 4.5 | 85% |
| Silicon oxide (SiOx) | 5.8 | 81% |
| Aluminum oxide (AlO) | 8.1 | 73% |
| Titanium nitride (TiN) | 9 | 70% |
| Nickel (Ni) | 13 | 57% |
| Hafnium zirconium oxide (HZO) | 30 | 0% |

Hence, any of the materials SiN, TaO, TaN, W, Mo, SiOx, AlO, TiN, and Ni can serve as the material of the layer of the layer of the stack of layers making up the FTJ that provides the biaxial stressing σ_{comp} and σₜₑₙₛ to the ferroelectric layer 24 during the anneal to promote formation of the ferroelectric crystallization in the orthorhombic (or other ferroelectric) phase during the anneal.

As one example, the top electrode layer 22 and/or the bottom electrode layer 20 may be in contact with the ferroelectric layer 24 and may be a titanium nitride layer, a tantalum nitride layer, a molybdenum layer, a tungsten layer, or a nickel layer, so as to provide the biaxial stressing σ_{comp} and σₜₑₙₛ to the ferroelectric layer 24 during the anneal to promote formation of the ferroelectric crystallization in the orthorhombic (or other ferroelectric) phase during the anneal.

As another example, the interfacial layer 26 in contact with the ferroelectric layer 24 may have a thickness of between about 0.2 nanometers and about 5 nanometers, and have a CTE that is at least about 25% lower than (and in some embodiments about one-half or less than) the CTE of the ferroelectric layer 24. The interfacial layer 26 may for example be a silicon oxide layer, a silicon nitride layer, or a metal oxide layer with suitably low CTE such as tantalum oxide or aluminum oxide. The interfacial layer 26 in these embodiments provides dual benefits of improving tunnel junction performance and promoting the ferroelectric phase crystallization during the anneal.

The resulting FTJ thus comprises a plurality of layers including at least the bottom electrode layer 20, the top electrode layer 22, and at least one ferroelectric layer 24 (possibly divided into layers 24₁ and 24₂ by an interposed interfacial layer 26 as shown in the embodiments of FIGS. 7, 10, 13, 16, and 19) disposed between the bottom electrode layer 20 and the top electrode layer 22, in which the at least one ferroelectric layer 24 comprises a ferroelectric material and has a thickness of about 5 nanometers or less, and in which at least one layer of the plurality of layers 20, 22, 24 is in contact with the ferroelectric layer and has a CTE that is at least about 25% lower than (and in some embodiment about one-half or less than) a CTE of the ferroelectric layer. In some embodiments the plurality of layers further includes an interfacial layer 26 having a thickness of between about 0.2 nanometers and about 5 nanometers which is also disposed between the bottom electrode layer 20 and the top electrode layer 22, the interfacial layer being in contact with the ferroelectric layer 24 and having a CTE that is at least about 25% lower than the CTE of the ferroelectric layer 24. In such FTJ devices, the ferroelectric layer 24 after the anneal of FIG. 1 part (B) is under tensile strain (σₜₑₙₛ) in a room temperature range of 20 °C to 25 °C.

With returning reference to FIG. 1 part (A), in some embodiments a transistor 50 is operatively connected with the FTJ 10A to form a ferroelectric random access memory (FeRAM) cell. The illustrative FeRAM cell of FIG. 1 part (A) connects the FTJ 10A between the source (or drain) contact of the transistor 50 (which may, for example, comprise a field effect transistor, FET, or the like) and electrical ground. In the FeRAM, the FTJ 10A acts as a switchable capacitor whose capacitance depends on whether the ferroelectric layer 24 is in the positive remnant polarization (+Pr) state or the negative remnant polarization (−Pr) state. The channel current of the transistor 50 can be controlled to switch the ferroelectric layer 24 of the FTJ 10A between the positive and negative remnant polarization states. While illustrated in FIG. 1 part (A), it will be appreciated that the transistor 50 could be similarly combined with any of the variant FTJ 10A embodiments of FIGS. 8-10; any of the FTJ 10B embodiments of FIG. 2 or 11-13; any of the FTJ 10C embodiments of FIG. 3 or 14-16; or any of the FTJ 10D embodiments of FIG. 4 or 17-19; to form an FeRAM cell, or can be combined with another FTJ having a ferroelectric tunnel junction stack as shown in any of FIGS. 5-7. In a typical FeRAM array, the transistors 50 of the FeRAM cells are fabricated during front end-of-line (FEOL) on the surface of and/or in the semiconductor substrate (e.g. semiconductor wafer, not shown), while the FTJ 10A and associated connectivity provided by the metallization layers Mₓ₋₁, Mₓ and vias Vₓ₋₁ are typically fabricated during MEOL and/or BEOL processing. Advantageously, the approaches disclosed herein for facilitating ferroelectric phase crystallization in the ferroelectric layer 24 by annealing does not entail adding any additional layer to the FTJ (such as a dedicated crystallization seed layer), and hence is readily combined with logic processing as an embedded FeRAM memory array.

Furthermore, while the illustrative example of FIG. 1 part (A) operatively connects the channel of the transistor 50 with FTJ 10A to form a ferroelectric random access memory (FeRAM) cell, other designs are contemplated, such as an Fe-RAM in which the FTJ is sandwiched between the gate electrode and source-drain channel of the FET so that the variable capacitance of the FTJ adjusts the gate voltage. Thus, more generally a transistor 50 is operatively connected with the ferroelectric tunnel junction 10A to form the FeRAM cell.

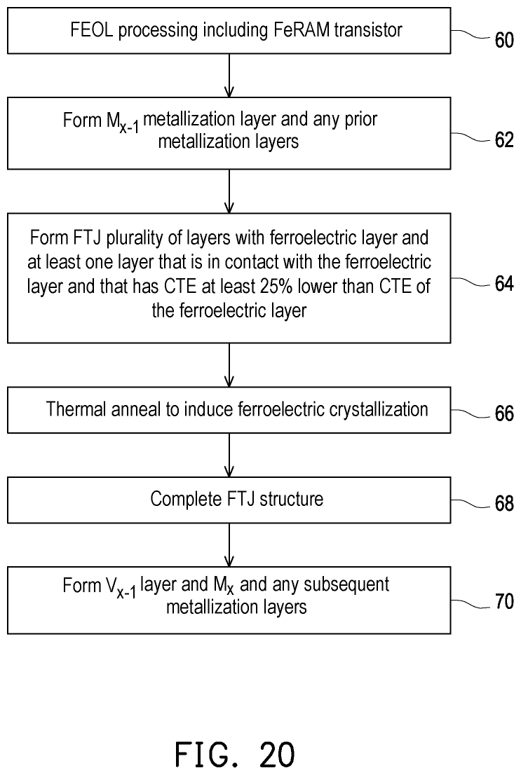

With reference now to FIG. 20, a fabrication method is described for fabricating a FeRAM such as that depicted in FIG. 1 part (A), including an FTJ such as the FTJ 10A. In an operation 60, FEOL processing is performed to fabricate transistors and other integrated circuit (IC) elements on and/or in a semiconductor wafer. This includes fabricating the FeRAM transistor 50 (see FIG. 1 part (A)) for each FeRAM cell. The FEOL processing 60 may include fabrication of other IC components such as logic circuitry and circuitry for interconnecting such logic circuitry with the FeRAM array, by way of nonlimiting illustrative example. The FEOL processing 60 may employ any suitable IC fabrication technology, such as by way of one nonlimiting illustration a CMOS fabrication technology.

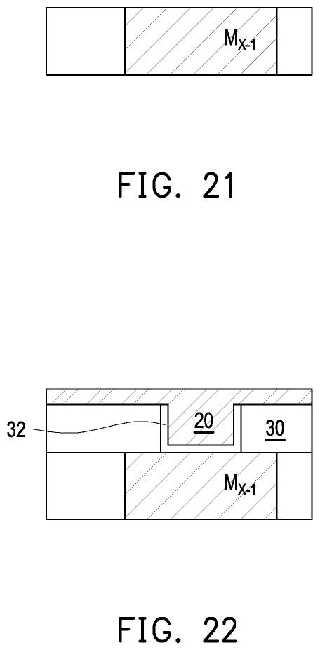

With continuing reference to FIG. 20 and with further reference to FIG. 21, in an operation 62, one or more metallization layers (and intervening via layers, as appropriate) are formed up to and including the metallization layer Mₓ₋₁ intended to contact the bottom electrode of the FTJ. This can employ any typical BEOL or MEOL processing sequence, such as depositing an intermetal dielectric (IMD), performing photolithographically controlled etching to form via openings in the IMD, filling the via openings to form electrical vias, depositing a continuous copper, copper alloy, or other suitable metal layer and patterning the metal layer to define the metallization pattern, and repeating for each successive metallization layer up to and including the Mₓ₋₁ metallization layer depicted in FIG. 1 part (A). FIG. 21 illustrates a portion of the Mₓ₋₁ metallization layer where the FTJ 10A is to be fabricated.

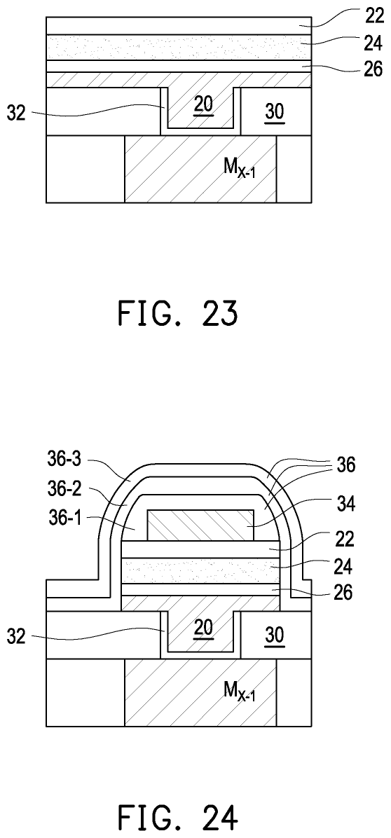

With continuing reference to FIG. 20 and with further reference to FIGS. 22 and 23, in an operation 64, the plurality of layers 20, 22, 24, and optionally 26 of the FTJ are formed. These may have the structure of the FTJ 10A of FIG. 1 part (A) as shown in FIGS. 22 and 23, or another variant FTJ 10A structure such as one of those shown in FIGS. 8-10, or may have another chosen FTJ structure such as one of the FTJ 10B embodiments of FIG. 2 or FIGS. 11-13, or of one of the FTJ 10C embodiments of FIG. 3 or FIGS. 14-16, or of one of the FTJ 10D embodiments of FIG. 4 or FIGS. 17-19, by way of some nonlimiting illustrative examples. In the example of FIGS. 22 and 23, the operation 64 includes forming the bottom electrode 20 with the hard mask 32 delineating the connection to the underlying contact of the Mₓ₋₁ layer as shown in FIG. 22, followed by deposition of the interfacial layer 26, the ferroelectric layer 24, and the top electrode layer 22 in that order, as shown in FIG. 23. The plurality of layers more generally include a ferroelectric layer 24 which may be of thickness about 5 nm or less, and also include at least one layer that is in contact with the ferroelectric layer 24 and that has a CTE at least about 25% lower than the CTE of the ferroelectric layer 24. The formation operation 64 typically includes various material deposition steps employing one or more deposition techniques such as chemical vapor deposition (CVD), physical vapor deposition (PVD), atomic layer deposition (ALD), various combinations thereof, and/or so forth.

In an operation 66, a thermal anneal is performed to induce ferroelectric crystallization of at least a suitable fraction of the ferroelectric layer 24. The thermal anneal can employ an anneal schedule such as that previously described with reference to FIG. 1 part (B). For an example in which the ferroelectric layer 24 comprises HZO, the ferroelectric phase crystallization produced by the anneal may be at least 35% orthorhombic crystal phase, or at least 50% orthorhombic crystal phase, or at least 70% orthorhombic crystal phase, in some nonlimiting illustrative examples. The remainder of the HZO may, for example, be in a tetragonal phase and/or a monoclinic phase or so forth.

With continuing reference to FIG. 20 and with further reference to FIG. 24, in an operation 68 the FTJ structure is completed. Depending on the specific FTJ structure, this may include deposition of additional layers and/or etching thereof, such as to form the optional elements such as dielectric spacers 36 as shown in FIG. 24. For example, etching may be done using a plasma etch, e.g. an isotropic chlorine or fluorine plasma etch as specific examples. Such etching may be done in conjunction with photolithographic patterning of a mask to delineate the etched areas, for example in the example of FIG. 24 to form the second hard mask region 34 of the FTJ 10A of FIG. 1 part (A) that spatially delineate etching processes. These are merely some nonlimiting illustrative fabrication examples. The operation 64 may include deposition of additional layers and/or etching thereof, such as to form the optional elements such as the illustrative dielectric spacer 36-1, the illustrative top etch stop layer 36-2, and the illustrative protective liner layer 36-3, and/or other features such as additional/other insulating layers or coatings, stress release features, or the like. FIG. 24 illustrates a resulting FTJ cell, but in some embodiments such processing may be performed to form a two-dimensional array of such FTJ cells from the layers deposited in FIG. 23.

In an operation 70, the Vₓ₋₁ via layer is formed, along with the Mₓ metallization layer and any subsequent metallization layers, using processing similar to that described previously for operation 62. Performing such processing on the FTJ cell shown in

FIG. 24 results in the completed FTJ 10A of FIG. 1, part (A) for the illustrative example. The metallization layers deposited in the operations 62 and/or 70 serve to electrically connect the FeRAM transistors 50 of the FeRAM cells with their corresponding FTJ 10A to provide electrical interconnections for the FeRAM array. The metallization layers deposited in the operations 62 and/or 70 may also serve to electrically interconnect the FeRAM array with logic IC circuitry or the like.

In the illustrative fabrication process of FIG. 20, the thermal anneal 66 is performed after deposition of the FTJ layers in operation 64 and as shown in FIG. 23 in the illustrative example, and before the subsequent FTJ fabrication and metallization steps 68 and 70. However, more generally, the thermal anneal 66 can be performed at any point in the fabrication process after the formation of the ferroelectric layer 24 and the at least one layer that is in contact with the ferroelectric layer 24 and that has a CTE at least about 25% lower than the CTE of the ferroelectric layer 24. This ensures that the at least one layer in contact with the ferroelectric layer 24 with CTE at least about 25% lower than the CTE of the ferroelectric layer 24 is present to provide the biaxial stressing previously described so as to promote formation of the ferroelectric crystallization phase (e.g. the orthorhombic phase in embodiments in which the ferroelectric layer is an HZO layer). In the illustrative example of FIGS. 21-24, the thermal anneal 66 is performed after deposition of the top electrode layer 22 but before deposition of the dielectric spacers 36 of the FTJ 10A of FIG. 1 part (A). This can be appropriate if one or more of those additional layers 36 cannot withstand the anneal temperature. In another example, the thermal anneal 66 could instead be performed after a portion or all of the metallization steps 70. The timing of the thermal anneal 66 in the fabrication process is suitably chosen based on considerations such as ensuring the anneal 66 is performed before formation of any later-formed elements that might be degraded by annealing, such as formation of any capacitor devices as part of the upper metallization steps 70.

In the following, some further embodiments are described.

In a nonlimiting illustrative embodiment, a method of manufacturing a device is disclosed. The method includes: forming a ferroelectric tunnel junction comprising a plurality of layers including at least a bottom electrode layer, a top electrode layer, and at least one ferroelectric layer disposed between the bottom electrode layer and the top electrode layer, wherein the at least one ferroelectric layer comprises a ferroelectric material and has a thickness of about 5 nanometers or less and wherein at least one layer of the plurality of layers is in contact with the ferroelectric layer and has a coefficient of thermal expansion that is at least about 25% lower than a coefficient of thermal expansion of the ferroelectric layer; and inducing ferroelectric phase crystallization in the ferroelectric layer by annealing the plurality of layers.

In a nonlimiting illustrative embodiment, a device comprises a ferroelectric tunnel junction comprising a plurality of layers, including at least: a bottom electrode layer, a top electrode layer, at least one ferroelectric layer disposed between the bottom electrode layer and the top electrode layer, and an interfacial layer disposed between the bottom electrode layer and the top electrode layer. The interfacial layer is in contact with the at least one ferroelectric layer and has a coefficient of thermal expansion that is at least about 25% lower than the coefficient of thermal expansion of the ferroelectric layer.

In a nonlimiting illustrative embodiment, a method of manufacturing a device is disclosed. The method includes: forming a ferroelectric tunnel junction comprising a plurality of layers including at least a bottom electrode layer, a top electrode layer, and at least one ferroelectric layer disposed between the bottom electrode layer and the top electrode layer, wherein the at least one ferroelectric layer comprises a ferroelectric material and wherein at least one layer of the plurality of layers is in contact with the ferroelectric layer and has a coefficient of thermal expansion that is at least 25% lower than a coefficient of thermal expansion of the ferroelectric layer; and inducing ferroelectric phase crystallization in the ferroelectric layer by annealing the plurality of layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a device, the method comprising:
forming a ferroelectric tunnel junction stack including at least:
a first electrode layer,
a second electrode layer,
an interfacial layer disposed between the first and second electrode
layers, and
at least one ferroelectric layer comprising ferroelectric SrBi₂Ta₂O₉,
PbZrₓTi₁₋ₓ O₃, or BaTiO3 disposed between the first and second electrode layers; and
inducing ferroelectric phase crystallization in the at least one ferroelectric layer by applying compressive biaxial stress to the at least one ferroelectric layer using the interfacial layer over a high temperature time period during which the ferroelectric tunnel junction stack is at an anneal temperature.

2. The method of claim 1, wherein the inducing of the ferroelectric phase crystallization further includes applying tensile biaxial stress to the at least one ferroelectric layer using the interfacial layer during a cooldown time period following the high temperature time period.

3. The method of claim 1, wherein the first electrode layer and/or the second electrode layer is in contact with the at least one ferroelectric layer and is a titanium nitride layer, a tantalum nitride layer, a molybdenum layer, a tungsten layer, or a nickel layer.

4. The method of claim 1, wherein the at least one ferroelectric layer has a thickness of 5 nanometers or less.

5. The method of claim 1, wherein the interfacial layer is a silicon nitride layer, a tantalum nitride layer, a tungsten layer, a molybdenum layer, a titanium nitride layer, or a nickel layer.

6. The method of claim 1, wherein the interfacial layer is a silicon nitride layer, a tantalum nitride layer, or a titanium nitride layer.

7. The method of claim 1, wherein the interfacial layer is a tungsten layer, a molybdenum layer, or a nickel layer.

8. The method of claim 1, wherein the at least one ferroelectric layer comprises first and second ferroelectric layers and the interfacial layer is disposed between the first and second ferroelectric layers and in contact with each of the first and second ferroelectric layers.

9. A device comprising:
a ferroelectric tunnel junction comprising a plurality of layers including a first electrode layer and a second electrode layer and further including:
a first ferroelectric layer disposed between the first electrode layer and the second electrode layer,
a second ferroelectric layer disposed between the first electrode layer and the second electrode layer, and
an interfacial layer disposed between the first and second ferroelectric layers and contacting each of the first ferroelectric layer and the second ferroelectric layer;
wherein the interfacial layer is a silicon nitride layer, a tantalum nitride layer, a tungsten layer, a molybdenum layer, a titanium nitride layer, or a nickel layer.

10. The device of claim 9, wherein:
the first electrode layer is in contact with the first ferroelectric layer, and/or the second electrode layer is in contact with the second ferroelectric layer.

11. The device of claim 9, wherein combined thicknesses of the first ferroelectric layer and the second ferroelectric layer is 5 nanometers or less.

12. The device of claim 9, wherein the interfacial layer is a silicon nitride layer.

13. The device of claim 9, wherein the first ferroelectric layer and the second ferroelectric layer each comprises hafnium oxide doped with zinc, silicon, yttrium, aluminum, gadolinium, lanthanum, or strontium.

14. The device of claim 9, wherein the first ferroelectric layer and the second ferroelectric layer each comprises SrBi2Ta209, PbZrxTi1-x03, or BaTiO3.

15. The device of claim 9, further comprising:
a transistor operatively connected with the ferroelectric tunnel junction to form a ferroelectric random access memory (FeRAM) cell.

16. A method of manufacturing a device, the method comprising:
forming a ferroelectric tunnel junction stack including at least a first electrode layer, a second electrode layer, and a ferroelectric layer disposed between the first electrode layer and the second electrode layer, wherein the ferroelectric layer comprises a ferroelectric material; and
inducing ferroelectric phase crystallization in the ferroelectric layer by applying biaxial stress to the ferroelectric layer during an anneal of the ferroelectric tunnel junction stack using at least one layer of the ferroelectric tunnel junction stack that is in contact with the ferroelectric layer.

17. The method of claim 16, wherein the at least one layer of the ferroelectric tunnel junction stack that is in contact with the ferroelectric layer includes at least one of: a titanium nitride layer, a tantalum nitride layer, or a silicon nitride layer.

18. The method of claim 16, wherein the at least one layer of the ferroelectric tunnel junction stack that is in contact with the ferroelectric layer includes at least one of: a molybdenum layer, a tungsten layer, or a nickel layer.

19. The method of claim 16, wherein the ferroelectric tunnel junction stack further includes an interfacial layer, the interfacial layer being disposed between the first electrode layer and the second electrode layer, the interfacial layer being in contact with the ferroelectric layer and having a coefficient of thermal expansion that is at least 25% lower than a coefficient of thermal expansion of the ferroelectric layer.

20. The method of claim 19, wherein the ferroelectric layer comprises first and second ferroelectric layers and the interfacial layer is disposed between the first and second ferroelectric layers and is in contact with each of the first ferroelectric layer and the second ferroelectric layer.

25. The method of claim 18 wherein the interfacial layer is a silicon nitride layer, a tantalum nitride layer, a tungsten layer, a molybdenum layer, a titanium nitride layer, or a nickel layer.
